(19) United States
(12) Patent Application Publication
(10) Pub. No.: US 2011/0032011 A1
(43) Pub. Date: Feb. 10, 2011

(54) AUTO FREQUENCY CALIBRATOR, METHOD THEREOF AND FREQUENCY SYNTHESIZER USING IT

(75) Inventors: Yoo Hwan KIM, Yongin-si (KR); Yoo Sam Na, Seoul (KR); Byeong Hak Jo, Suwon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co.,Ltd., Suwon (KR)

(21) Appl. No.: 12/617,151

(22) Filed: Nov. 12, 2009

(30) Foreign Application Priority Data
Aug. 10, 2009 (KR) 10-2009-0073239

(51) Int. Cl. H03L 7/00

(52) U.S. Cl. 327/156; 331/10

(57) ABSTRACT

The present invention relates to and auto frequency calibrator, a method thereof, and a frequency synthesizer using it. The auto frequency calibrator includes a capacitor bank selector that is operated as an open loop and compares a frequency signal having integer-divided reference frequency with the reference frequency signal to select a capacitor bank corresponding to an output frequency; and a capacitor bank controller that is operated as a closed loop when the capacitor bank is selected and compares the output voltage corresponding to the output frequency with a preset voltage range to control the capacitor bank selected in the capacitor bank selector.

### CROSS REFERENCES RELATED APPLICATIONS

The present application claims priority under 35 U.S.C. 119 and 35 U.S.C. 365 to Korean Patent Application No. 10-2009-0073239 filed on Aug. 10, 2009, which is hereby incorporated by reference in its entirety.

### BACKGROUND OF THE INVENTION

1. Field of the Invention

The present invention relates to an auto frequency calibrator that is operated as an open loop or a closed loop to select a capacitor bank corresponding to a fractional-divided frequency signal so as to select a capacitor bank corresponding to an output frequency, a method of automatically calibrating a frequency, and a frequency synthesizer using it.

2. Description of the Related Art

Currently, in a frequency synthesizer used in mobile communication, a frequency range of a voltage controlled oscillator (VCO) is very wide.

In order to cover the wide frequency of the voltage controlled oscillator, a capacitor bank of the voltage controlled oscillator should be selected to be met with a desired frequency. Meanwhile, automatically selecting the capacitor bank of the voltage controlled oscillator according to the desired frequency is called auto frequency calibrator (AFC).

The auto frequency calibrator according to the related art is operated as an open loop to select the capacitor bank. A process of selecting the capacitor bank as the open loop considers only an integer divider value.

When the auto frequency calibration ends, after a switch is closed in the open loop to form a closed loop, the voltage controlled oscillator generates the corresponding frequency. At this time, the voltage controlled oscillator cannot generate the frequency corresponding to the selected capacitor bank because of the fractional value by a sigma delta of the closed loop, such that it can be unlocked.

In addition, since the selected capacitor bank does not reflect the change according to temperature, the frequency synthesizer may be unlocked and since a gain of the voltage controlled oscillator is not constant, the characteristics of the frequency synthesizer are deteriorated.

FIGS. 1 and 2 are diagrams showing a schematic configuration of a general frequency synthesizer.

As shown in FIG. 1, a general frequency synthesizer includes an oscillator 11, a phase frequency divider (PFD) 13, a charge pump (CP) 14, a low pass filter (LPF) 15, a voltage controlled oscillator (VCO) 16, an auto frequency calibrator 17, a divider 18, and a sigma-delta divider 19.

The phase frequency divider 13 detects phases of a divided frequency Fdiv and a reference frequency Fref that are input and transfers a signal corresponding to the difference to the charge pump 14. The charge pump 14 controls charges and then provides them to an input of the voltage controlled oscillator 16 via the low pass filter 15 to generate a desired frequency.

FIG. 2 is a diagram showing a schematic configuration of a fractional frequency synthesizer of a high frequency band, which further includes a prescaler.

The prescaler 20 is added to control an operational speed of the divider 18 when a frequency generated in the voltage controlled oscillator 16 becomes high.

For example, when a divider value of the prescaler is 2, an output frequency of the voltage controlled oscillator 16 can be calculated by Equation 1.

FvcoFref*(PA+B)*2=Fref*N*2 [Equation 1]

where Evco indicates the output frequency of the voltage controlled oscillator 16, Fref indicates the reference frequency of the oscillator 11, and N (or PA+B) indicates the divider value.

If only the integer divider value of Fvco is applied, Fvco=Fref*2. However, if the fractional divider value is applied, when a bit used in the signal delta divider 19 is 20 bits, Fvoo′=Fref/(2̂20−1) such that the fractional divider value is not reflected when using the frequency synthesizer in the related art.

Therefore, in order to generate the desired frequency in the voltage controlled oscillator 16, when selecting the capacitor bank using the auto frequency calibrator 17, only the characteristic of the integer divider value is considered. For this reason, it becomes the closed loop and then does not apply the fractional divider value, which causes several problems.

For example, when Fref=40 Mhz, Kvco=20M/V N=25, and .F=0.975 and the voltage of the voltage controlled oscillator 16 is V_{DD}/2 in the open loop, the auto frequency calibrator 17 selects a first capacitor bank.

When the capacitor bank is selected in the open loop and the closed loop is formed, the integer divider value N as well as the fractional divider value (.F) is considered to determine all the divider values, such that there is a difference in the output frequency of the voltage controlled oscillator 16.

In other words, the output frequency (Fvco_open loop) of the voltage controlled oscillator 16 of the open loop is calculated by Fref*N*2, such that it becomes 2 GHz, while the output frequency (Fvco_closed loop) of the voltage controlled oscillator 16 of the closed loop is calculated by Fref*N′*2, such that it becomes 2.078 GHz.

As shown in FIG. 3, since the capacitor bank meeting the calculated Fvco_closed loop becomes a fifteenth bank and the first capacitor bank selected in the open loop exists only in the range of 1.9985 GHz to 2.015 GHz, there is no capacitor bank corresponding to 2.078 GHz, which is the output frequency of the voltage controlled oscillator 16 in the case of considering the fractional divider value .F, such that the frequency synthesizer becomes an unlock state.

Further, reviewing the frequency characteristic of the general voltage controlled oscillator 16 (see FIG. 3), the entire gain of the voltage controlled oscillator 16 is non-linear when voltage becomes high (B) and low (A), such that the frequency characteristic indicates a characteristic different from a linear interval.

When the capacitor bank is selected in the intervals A and B where the frequency characteristic curve of the voltage controlled oscillator 16, the gain value of the voltage controlled oscillator is non-constant, such that all the characteristics of the frequency synthesizer are changed.

Therefore, when the voltage controlled oscillator 16 selects the capacitor bank in the non-linear interval, a time constant of the charge pump or a loop filter should be compensated, such that the entire noise characteristic of the frequency synthesizer is degraded and the system is complicated.

### SUMMARY OF THE INVENTION

The present invention provides an auto frequency calibrator that selects a capacitor bank corresponding town integer-divided frequency signal and then forms a closed loop and detects an output voltage corresponding to an output frequency of the closed loop to control the capacitor bank to a capacitor bank corresponding to a fractional-divided frequency signal, a method of automatically calibrating a frequency, and a frequency synthesizer using it.

According to another feature of the present invention, there is provided an auto frequency calibrator, including: a capacitor bank selector that is operated as an open loop and compares a frequency signal having integer-divided reference frequency with the reference frequency signal to select a capacitor bank corresponding to an output frequency; and a capacitor bank controller that is operated as a closed loop when the capacitor bank is selected and compares the output voltage corresponding to the output frequency with a preset voltage range to control the capacitor bank selected in the capacitor bank selector.

Preferably, the output voltage is fixed to a value corresponding to V_{DD}/2 while the auto frequency calibrator according to the present invention is operated as the open loop.

Preferably, the capacitor bank selector of the auto frequency calibrator according to the present invention includes: a first counter that counts the frequency signal having an integer-divided reference frequency; a second counter that counts the reference frequency signal; a comparator that compares signals counted in the first counter and the second counter; and a capacitor bank selection controller that generates a control signal controlling the selection of the capacitor bank from the compared signals.

Preferably, the capacitor bank selection controller of the auto frequency calibrator according to the present invention compares the frequency signal having an integer-divided reference frequency with the reference frequency signal in the first counter or the second counter to generate a control signal that selects the capacitor bank up or down.

Preferably, the capacitor bank controller of the auto frequency calibrator according to the present invention includes: a first voltage comparator that compares an output voltage corresponding to the output frequency with a preset maximum voltage; a second voltage comparator that compares the output voltage corresponding to the output frequency with a preset minimum voltage; and a capacitor bank control controller that compares the maximum voltage or the minimum voltage with the output voltage in the first voltage comparator or the second voltage comparator to generate a control signal controlling the capacitor bank up or down.

According to another feature of the present invention, there is provided a frequency synthesizer, including: an auto frequency calibrator including a capacitor bank selector that is operated as an open loop and compares a frequency signal having an integer-divided frequency signal with the reference frequency signal to select a capacitor bank corresponding to an output frequency and a capacitor bank controller that forms a closed loop when the capacitor bank is selected and compares the output voltage corresponding to the output frequency with a preset voltage range to control the capacitor bank selected in the capacitor bank selector; and a loop switching element that forms the closed loop when the capacitor bank is selected in the capacitor bank selector to detect the output voltage corresponding to the output frequency.

Preferably, the capacitor bank selector of the frequency synthesizer according to the present invention includes: a first counter that counts the frequency signal having an integer-divided reference frequency; a second counter that counts the reference frequency signal; a comparator that compares signals counted in the first counter and the second counter; and a capacitor bank selection controller that controls the selection of the capacitor bank from the compared signals.

Preferably, the capacitor bank selection controller of the frequency synthesizer according to the present invention compares the output voltage with the maximum voltage or the minimum voltage in a first comparator or a second comparator to generate a control signal selecting the capacitor bank up or down.

Preferably, the capacitor bank controller of the frequency synthesizer according to the present invention includes: a first voltage comparator that compares an output voltage corresponding to the output frequency with a preset maximum voltage; a second voltage comparator that compares the output voltage corresponding to the output frequency with a preset minimum voltage; and a capacitor bank control controller that compares the maximum voltage or the minimum voltage with the output voltage in the first voltage comparator or the second voltage comparator to generate a control signal controlling the capacitor bank up or down.

Preferably, in the frequency synthesizer according to the present invention, the output frequency is generated by comparing the reference frequency signal with a signal having fractional-divided reference frequency signal when the closed loop is formed.

Preferably, the frequency synthesizer according to the present invention further includes a voltage controlled oscillator that includes a plurality of capacitor that are connected to each other in parallel and a switching element that can switch each capacitor and outputs an oscillation frequency corresponding to the capacitor bank controlled in the capacitor bank controller of the auto frequency calibrator.

Preferably, the output voltage is fixed to a value corresponding to V_{DD}/2 while the frequency synthesizer according to the present invention is operated as the open loop.

According to still another feature of the present invention, there is provided a method of automatically calibrating a frequency selecting a capacitor bank operated as an open loop according to an integer-divided frequency signal and then controlling the capacitor bank operated as a closed loop by measuring an output voltage, including: selecting the capacitor bank that is operated as the open loop and corresponds to an output frequency by comparing a reference frequency signal with an integer-divided frequency signal; and controlling the capacitor bank selected in the capacitor bank selector by forming the closed loop when the capacitor bank is selected and comparing the output voltage corresponding to the output frequency with a preset voltage range.

Preferably, in the method of automatically calibrating a frequency according to the present invention, the selecting the capacitor bank includes: fixing the output voltage to V_{DD}/2; maintaining the fixed output voltage and comparing the reference frequency signal with the integer-divided frequency signal; and comparing a size of the reference frequency signal with a size the integer-divided frequency signal to control the capacitor bank corresponding to the integer-divided frequency signal up or down and change the capacitor bank to a capacitor bank corresponding to the reference frequency signal.

Preferably, in the method of automatically calibrating a frequency according to the present invention, the controlling the capacitor bank includes: forming the closed loop by connecting a loop switching element; maintaining the closed loop and measuring the output voltage; comparing the measured output voltage with a preset maximum or minimum voltage; and controlling the capacitor bank up when the measured output voltage is larger than the maximum voltage and controlling the capacitor bank down when the measured output voltage is smaller than the minimum voltage.

In the embodiment of the present invention, the auto frequency calibrator, which finds out the capacitor bank corresponding to the desired output frequency, can reflect the integer divider value as well as the fractional divider value and the gain of the voltage controlled oscillator can select a constant interval to prevent the loop of the frequency synthesizer from being unlocked.

Further, there is no need to control the value of the charge pump or the loop filter according to the gain change in the frequency range of the voltage controlled oscillator such that the degradation of the noise characteristic of the frequency synthesizer can be degraded and the complication of the circuit design can be prevented.

### BRIEF DESCRIPTION OF THE DRAWINGS

FIGS. 1 and 2 are diagrams showing a schematic configuration of a general frequency synthesizer;

FIG. 3 is a diagram showing a frequency characteristic change of a voltage controlled oscillator used in a general frequency synthesizer;

FIG. 4 is a diagram showing a configuration of an auto frequency calibrator according to an exemplary embodiment of the present invention;

FIG. 5 is a diagram showing a flowchart of a method of automatically calibrating a frequency according to an exemplary embodiment of the present invention;

FIG. 6 is a diagram showing simulation results for describing a method of selecting and controlling the capacitor bank of the auto frequency calibrator according to the exemplary embodiment of the present invention; and

FIG. 7 is a diagram showing digital bits corresponding to the capacitor banks found in the auto frequency calibrator.

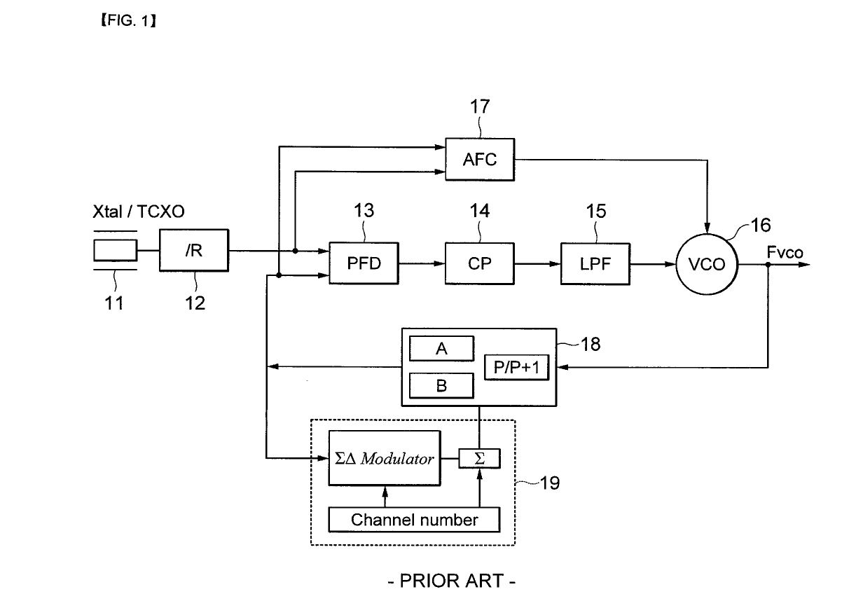

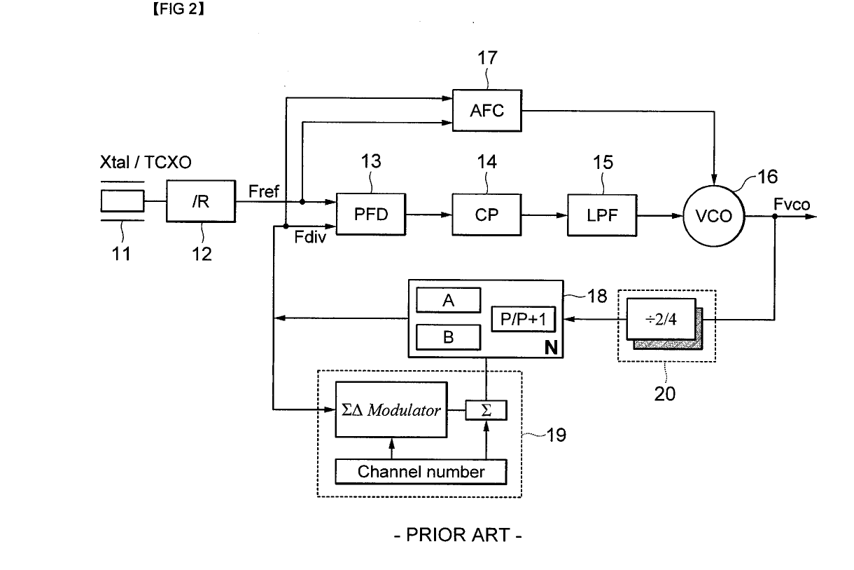

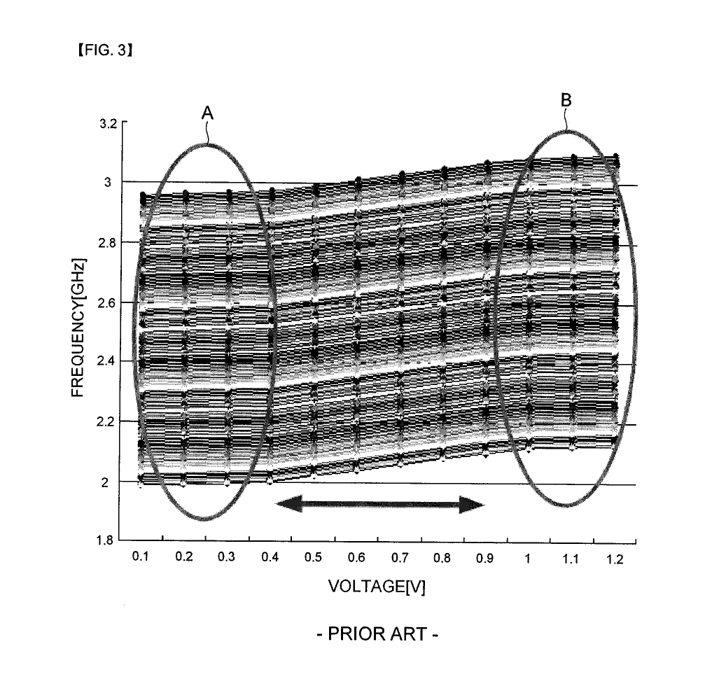

### DETAILED DESCRIPTION OF THE PREFERRED EMBODIMENTS

Although the present invention can be modified variously and have several embodiments, the exemplary embodiments are illustrated in the accompanying drawings and will be described in detail in the detailed description. However, the present invention is not limited to the specific embodiments and should be construed as including all the changes, equivalents, and substitutions included in the spirit and scope of the present invention.

Hereinafter, an auto frequency calibrator, a method of automatically calibrating a frequency, and a frequency synthesizer using it according to the exemplary embodiment of the present invention will be described with reference to the accompanying drawings. Like reference numerals refer to like components and the duplicated description thereof will be omitted.

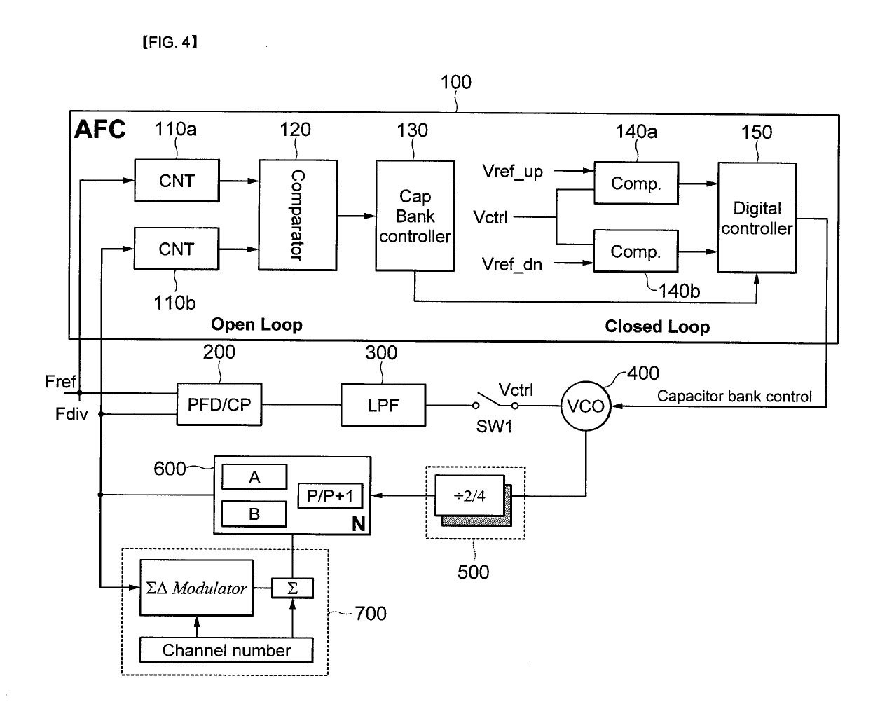

FIG. 4 is a diagram showing a configuration of an auto frequency calibrator according to an exemplary embodiment of the present invention.

As shown in FIG. 4, an auto frequency calibrator 100 includes a capacitor bank selector and a capacitor bank controller. The capacitor bank selector includes a first counter 110a, a second counter 110b, a comparator 120, and a capacitor bank selection controller 130. The capacitor bank controller includes a first voltage comparator 140a, a second voltage comparator 140b, and a capacitor bank control controller 150.

The capacitor bank selector is operated as an open loop and compares a frequency signal having an integer-divided frequency signal with the reference frequency signal to select a capacitor bank corresponding to an output frequency.

The capacitor bank controller is operated as a closed loop when the capacitor bank is selected and compares the output voltage corresponding to the output frequency with a predetermined voltage range to control the capacitor bank selected in the capacitor bank selector.

In other words, the capacitor bank selector considers only the integer divider value to select the capacitor bank and the capacitor bank controller reflects a fractional divider value to control the capacitor bank.

While the frequency synthesizer is operated as the open loop, an output voltage from an voltage controlled oscillator is fixed to a value corresponding to V_{DD}/2 and an output frequency signal corresponding to V_{DD}/2 is provided to the capacitor bank selector of the auto frequency calibrator.

First, the capacitor bank selector of the auto frequency calibrator is configured to include a first counter 110a, a second counter 110b, a comparator 120, and a capacitor bank selection controller 130, wherein the first counter 110b counts the frequency signal having an integer-divided frequency signal, which is generated from the oscillator and the second counter 110a counts the reference frequency signal.

The comparator 120 compares signals counted in the first counter 110b and the second counter 110a and the capacitor bank selection controller 130 generates a control signal that controls the selection of the capacitor bank from the compared signals.

In other words, the bank selection controller 130 compares the frequency signal having an integer-divided reference signal with the reference frequency signal in the first counter 110b or the second counter 110a to generate the control signal that selects the capacitor bank up or down.

Next, the capacitor bank controller of the auto frequency calibrator 100 includes the first voltage comparator 140a, the second voltage comparator 140b, and the capacitor bank control controller 150.

The first voltage comparator 140a compares the output voltage corresponding to the output frequency of the voltage controlled oscillator with a predetermined maximum voltage and the second voltage comparator 140b compares the output voltage corresponding to the output frequency with a predetermined minimum voltage.

The capacitor bank control controller 150 compares the maximum voltage or the minimum voltage with the output voltage in the first voltage comparator 140a or the second voltage comparator 140b to generate a control signal that controls the capacitor bank up or down.

Therefore, the auto frequency calibrator according to the related art, which is operated as the open loop and selects the capacitor bank in consideration of the fractional divider value, does not reflect any fractional divider values, while the auto frequency calibrator according to the present invention selects the capacitor bank in consideration of the integer divider value when it is operated as the open loop and can reflect any fractional divider value when it is operated as the closed loop to control the capacitor bank, such that there is no need to separately correct a charge pump or a loop pump when the auto frequency calibrator is operated as the closed loop.

The frequency synthesizer according to another embodiment of the present invention includes the auto frequency calibrator 100 and a loop switching element SW1.

The frequency synthesizer includes the auto frequency calibrator 100, a phase frequency divider (PFD) 200, a charge pump (CP) 200, a low pass filter (LPF) 300, an voltage controlled oscillator (VCO) 400, first and second dividers 500 and 600, and a signal-delta divider 700.

The auto frequency calibrator 100 has the above-mentioned features and the phase frequency divider (PFD) 200, the charge pump (CP) 200, the low pass filter (LPF) 300, the voltage controlled oscillator (VCO) 400, the first and second dividers 500 and 600, and the signal-delta divider 700 all of which are included in the frequency synthesizer according to an exemplary embodiment of the present invention have general characteristics.

The loop of the frequency synthesizer according to the exemplary embodiment of the present invention is operated as the open loop and the closed loop by the on/off of the loop switching element SW1 and transmits the control signal that closes the loop switching element SW1 to be operated as the closed loop when the capacitor bank is selected in the capacitor bank selector of the auto frequency calibrator 100.

In addition, the loop switching element SW1 detects an output voltage Vctrl corresponding to the output frequency of the voltage controlled oscillator 400 when it is operated as the closed loop and transmits the detected output voltage to the capacitor bank controller of the auto frequency calibrator 100.

The voltage controlled oscillator 400 includes a plurality of capacitors that are connected to each other in parallel and a switching element that can switch each capacitor and outputs an oscillation frequency corresponding to the capacitor bank controlled in the capacitor bank controller.

A method of automatically calibrating a frequency is a method that selects a capacitor bank, which is operated as an open loop, according to an integer-divided frequency signal and then controls the capacitor bank, which is operated as a closed loop, by measuring an output voltage.

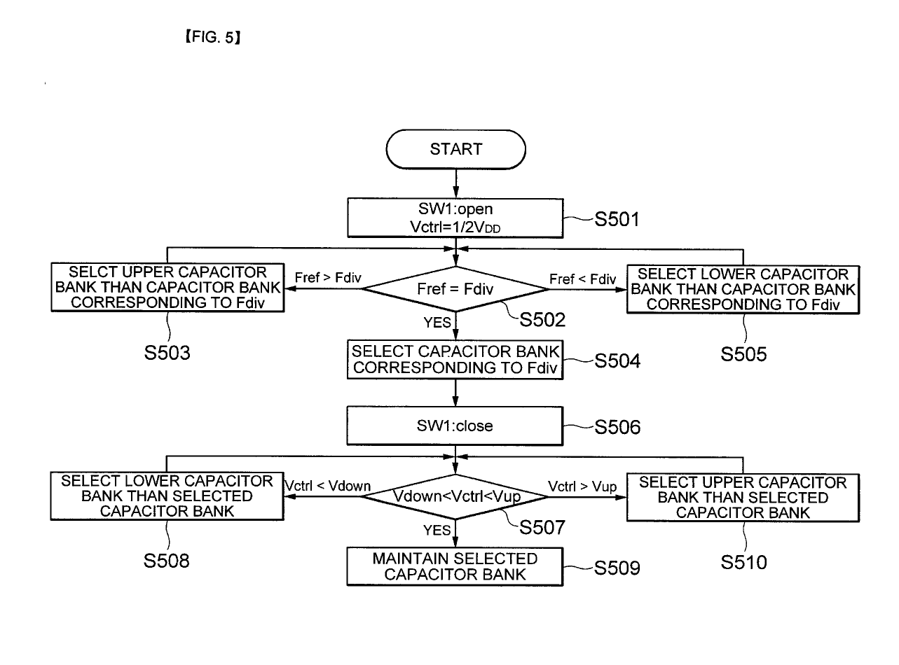

FIG. 5 is a diagram showing a flowchart of a method of automatically calibrating a frequency according to an exemplary embodiment of the present invention.

As shown in FIG. 5, the method of automatically calibrating a frequency according to an exemplary embodiment of the present invention opens the loop switching element SW1 so that the loop of the frequency synthesizer is operated as the open loop and initializes the output voltage Vctrl to V_{DD}/2 (S501) and then compares a reference frequency signal Fref with an integer-divided frequency signal Fdiv to select a capacitor bank corresponding to the output frequency (S502).

The method of automatically calibrating a frequency compares the reference frequency signal Fref with the integer-divided frequency signal Fdiv and controls the capacitor bank corresponding to the integer-divided frequency signal Fdiv up or down so that the integer-divided frequency signal Fdiv conforms to the reference frequency signal Fref (S502 to S504).

When the capacitor bank corresponding to the integer-divided frequency signal Fdiv is selected so that the integer-divided frequency signal Fdiv conforms to the reference frequency signal Fref, the loop switching element SW1 is closed to form the closed loop (S504).

When the closed loops is formed, the output voltage Vctrl corresponding to the output frequency of the voltage controlled oscillator compares with the predetermined voltage ranges Vdown and Vup to control the capacitor bank selected in the capacitor bank selector.

The controlling the capacitor bank (S506 to S510) includes forming the closed loop by connecting the loop switching element SW1 (S506), maintaining the closed loop and measuring the output voltage Vctrl, comparing the measured output voltage Vctrl with the predetermined maximum Vup or minimum voltage Vdown (S507), and controlling the capacitor bank up when the measured output voltage Vctrl is larger than the maximum voltage Vup (S510), and controlling the capacitor bank down when the measured output voltage Vctrl is smaller than the minimum voltage Vdown (S508).

In other words, after the capacitor bank is selected in consideration of the integer-divided frequency signal, the output voltage from the voltage controlled oscillator is detected to consider the linearity of the fractional-divided frequency and gain while the frequency synthesizer is operated as the closed loop and the capacitor bank is controlled so that the output voltage is included in the predetermined voltage range.

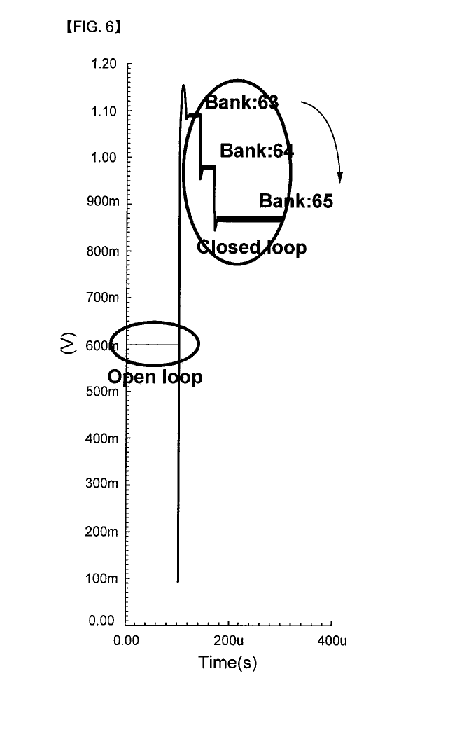

FIG. 6 is a diagram showing simulation results for describing a method of selecting and controlling the capacitor bank of the auto frequency calibrator according to the exemplary embodiment of the present invention.

FIG. 6 shows a process of operating the capacitor bank as the closed loop after the capacitor bank is selected in consideration of the integer divider value in the open loop and controlling the capacitor bank up or down by comparing the output voltage with the predetermined voltage range.

In other words, the capacitor banks Bank 63->Bank 64->Bank 65 are controlled down one by one by selecting the capacitor bank whose output voltage corresponds to 600 [mV] in the open loop and comparing the output voltage measured in the closed loop with the predetermined voltage range to control the capacitor bank so that the output voltage is included in the predetermined voltage range.

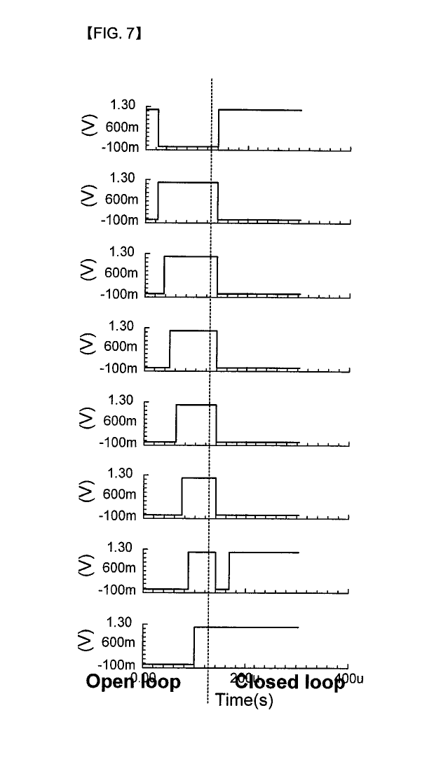

FIG. 7 shows digital bits corresponding to the capacitor banks found in the auto frequency calibrator. The auto frequency calibrator compares the reference frequency signal with the divided frequency signal while being operated as the open loop to change the digital bits into 10000000->01000000->01100000->01111000->01111110->01111111 and select digital bits 01111111 where the reference frequency signal conforms to the divided frequency signal.

When the final digital bits 01111111 of the open loop are selected, they are operated in the closed loop to change the digital bits into 01111111->10000001->10000011 according to the output voltage and to control the digital bits so that the output voltage is included in the predetermined voltage range.

Therefore, the final digital bits operated in the closed loop are output as 10000011.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An auto frequency calibrator, comprising:
a capacitor bank selector that is operated as an open loop and compares a frequency signal having integer-divided reference frequency with the reference frequency signal to select a capacitor bank corresponding to an output frequency; and
a capacitor bank controller that is operated as a closed loop when the capacitor bank is selected and compares the output voltage corresponding to the output frequency with a preset voltage range to control the capacitor bank selected in the capacitor bank selector.

2. The auto frequency calibrator according to claim 1, wherein the output voltage is fixed to a value corresponding to V_{DD}/2 while the auto frequency calibrator is operated as the open loop.

3. The auto frequency calibrator according to claim 1, wherein the capacitor bank selector includes:
a first counter that counts the frequency signal having an integer-divided reference frequency;
a second counter that counts the reference frequency signal;
a comparator that compares signals counted in the first counter and the second counter; and
a capacitor bank selection controller that generates a control signal controlling the selection of the capacitor bank from the compared signals.

4. The auto frequency calibrator according to claim 3, wherein the capacitor bank selection controller compares the frequency signal having an integer-divided reference frequency with the reference frequency signal in the first counter or the second counter to generate a control signal that selects the capacitor bank up or down.

5. The auto frequency calibrator according to claim 1, wherein the capacitor bank controller includes:
a first voltage comparator that compares an output voltage corresponding to the output frequency with a preset maximum voltage;
a second voltage comparator that compares the output voltage corresponding to the output frequency with a preset minimum voltage; and
a capacitor bank control controller that compares the maximum voltage or the minimum voltage with the output voltage in the first voltage comparator or the second voltage comparator to generate a control signal controlling the capacitor bank up or down.

6. A frequency synthesizer, comprising:
an auto frequency calibrator including a capacitor bank selector that is operated as an open loop and compares a frequency signal having an integer-divided frequency signal with the reference frequency signal to select a capacitor bank corresponding to an output frequency and a capacitor bank controller that forms a closed loop when the capacitor bank is selected and compares the output voltage corresponding to the output frequency with a preset voltage range to control the capacitor bank selected in the capacitor bank selector; and
a loop switching element that forms the closed loop when the capacitor bank is selected in the capacitor bank selector to detect the output voltage corresponding to the output frequency.

7. The frequency synthesizer according to claim 6, wherein the capacitor bank selector includes:
a first counter that counts the frequency signal having an integer-divided reference frequency;
a second counter that counts the reference frequency signal;
a comparator that compares signals counted in the first counter and the second counter; and
a capacitor bank selection controller that controls the selection of the capacitor bank from the compared signals.

8. The frequency synthesizer according to claim 7, wherein the capacitor bank selection controller compares the output voltage with the maximum voltage or the minimum voltage in a first comparator or a second comparator to generate a control signal selecting the capacitor bank up or down.

9. The frequency synthesizer according to claim 6, wherein the capacitor bank controller includes:
a first voltage comparator that compares an output voltage corresponding to the output frequency with a preset maximum voltage;
a second voltage comparator that compares the output voltage corresponding to the output frequency with a preset minimum voltage; and
a capacitor bank control controller that compares the maximum voltage or the minimum voltage with the output voltage in the first voltage comparator or the second voltage comparator to generate a control signal controlling the capacitor bank up or down.

10. The frequency synthesizer according to claim 6, wherein the output frequency is generated by comparing the reference frequency signal with a signal having fractional-divided reference frequency signal when the closed loop is formed.

11. The frequency synthesizer according to claim 6, further comprising a voltage controlled oscillator that includes a plurality of capacitor that are connected to each other in parallel and a switching element that can switch each capacitor and outputs an oscillation frequency corresponding to the capacitor bank controlled in the capacitor bank controller of the auto frequency calibrator.

12. The frequency synthesizer according to claim 6, wherein the output voltage is fixed to a value corresponding to V_{DD}/2 while the frequency synthesizer is operated as the open loop.

13. A method of automatically calibrating a frequency selecting a capacitor bank operated as an open loop according to an integer-divided frequency signal and then controlling the capacitor bank operated as a closed loop by measuring an output voltage, comprising:
selecting the capacitor bank that is operated as the open loop and corresponds to an output frequency by comparing a reference frequency signal with an integer-divided frequency signal; and
controlling the capacitor bank selected in the capacitor bank selector by forming the closed loop when the capacitor bank is selected and comparing the output voltage corresponding to the output frequency with a preset voltage range.

14. The method of automatically calibrating a frequency according to claim 13, wherein the selecting the capacitor bank includes:
fixing the output voltage to V_{DD}/2;
maintaining the fixed output voltage and comparing the reference frequency signal with the integer-divided frequency signal; and
comparing a size of the reference frequency signal with a size the integer-divided frequency signal to control the capacitor bank corresponding to the integer-divided frequency signal up or down and change the capacitor bank to a capacitor bank corresponding to the reference frequency signal.

15. The method of automatically calibrating a frequency according to claim 13, wherein the controlling the capacitor bank includes:
forming the closed loop by connecting a loop switching element;
maintaining the closed loop and measuring the output voltage;
comparing the measured output voltage with a preset maximum or minimum voltage; and
controlling the capacitor bank up when the measured output voltage is larger than the maximum voltage and controlling the capacitor bank down when the measured output voltage is smaller than the minimum voltage.
